(19) United States
(12) Patent Application Publication
(10) Pub. No.: US 2025/0374528 A1
(43) Pub. Date: Dec. 4, 2025

(54) INTEGRATED CIRCUIT DEVICES HAVING ENHANCED BACK-GATE SEPARATION PATTERNS THEREIN AND METHODS OF FABRICATING THE SAME

(71) Applicant: Samsung Electronics Co., Ltd., Suwon-si (KR)

(72) Inventors: Hyejeong Jeong, Suwon-si (KR); Byeng Ha Ko, Suwon-si (KR); Geumbi Mun, Suwon-si (KR); Yoonji Lee, Suwon-si (KR); Ik Soo Kim, Suwon-si (KR); Hyunjin Lee, Suwon-si (KR)

(21) Appl. No.: 18/974,494

(22) Filed: Dec. 9, 2024

(30) Foreign Application Priority Data
May 28, 2024 (KR) 10-2024-0069360

(51) Int. Cl. H10B 12/00

(52) U.S. Cl. CPC H10B 12/482; H10B 12/315

(57) ABSTRACT

An integrated circuit device includes a substrate and a bit line extending in a first direction thereon. A plurality of semiconductor patterns are provided, which extend on the bit line, along with a back-gate electrode, which extends between the plurality of semiconductor patterns and in a second direction different from the first direction. A back-gate separation pattern is provided, which extends on a bottom surface of the back-gate electrode and between the plurality of semiconductor patterns. The back-gate separation pattern may include an insulating material, which has a dielectric constant lower than a dielectric constant of SiON and has an impurity therein selected from a group consisting of nitrogen (N) and fluorine (F).

### REFERENCE TO PRIORITY APPLICATION

This U.S. non-provisional patent application claims priority under 35 U.S.C. § 119 to Korean Patent Application No. 10-2024-0069360, filed May 28, 2024, the disclosure of which is hereby incorporated herein by reference.

### BACKGROUND

The present disclosure relates to integrated circuit devices and, in particular, to integrated circuit memory devices and methods of fabricating the same.

Due to their small-sized, multifunctional, and/or low-cost characteristics, integrated circuit devices are being utilized as important elements in the electronics industry. The integrated circuit devices are often classified into a semiconductor memory device for storing data, a semiconductor logic device for processing data, and a hybrid integrated circuit device including both of memory and logic elements.

Due to the recent increasing demand for electronic devices with a fast speed and/or low power consumption, the integrated circuit device requires a fast operating speed and/or a low operating voltage. To satisfy the requirement, it is necessary to increase an integration density of the integrated circuit device. Thus, many studies are being conducted to realize a highly integrated circuit device, including highly integrated memory devices.

### SUMMARY

An embodiment of the inventive concept provides an integrated circuit device with improved reliability and productivity and a method of fabricating the same.

According to an embodiment of the inventive concept, an integrated circuit device includes a substrate and a bit line extending in a first direction thereon. A plurality of semiconductor patterns are provided, which extend on the bit line, along with a back-gate electrode, which extends between the plurality of semiconductor patterns and in a second direction different from the first direction. A back-gate separation pattern is provided, which extends on a bottom surface of the back-gate electrode and between the plurality of semiconductor patterns. The back-gate separation pattern may include an insulating material, which has a dielectric constant lower than a dielectric constant of SiON and has an impurity therein selected from a group consisting of nitrogen (N) and fluorine (F). Moreover, in some embodiments, an atomic concentration of the impurity in the insulating material may be in a range from 0.5 at % to 15 at %. For example, in the event the impurity is N, then an atomic concentration may be in a range from 0.5 at % to 5 at %; however, if the impurity is F, then the atomic concentration may be in a range from 0.5 at % to 15 at %, according to some embodiments.

According to another embodiment of the inventive concept, an integrated circuit device may include a substrate, a bit line extending in a first direction relative to a top surface of the substrate, semiconductor patterns provided on the bit line and extended in another direction relative to the top surface of the substrate, a back-gate electrode provided between the semiconductor patterns and extended in a second direction, which is unequal to the first direction, and a separation pattern on a bottom surface of the back-gate electrode. The separation pattern may be interposed between the semiconductor patterns, and the separation pattern may include an insulating material and an impurity in the insulating material. The impurity may include at least one of N or F, and an atomic concentration of the impurity may range from 0.5 at % to 15 at %.

According to an embodiment of the inventive concept, an integrated circuit device may include a substrate, a bit line extending in a first direction parallel to a top surface of the substrate, a plurality of semiconductor patterns provided on the bit line and extended in a direction perpendicular to the top surface of the substrate, with each of the semiconductor patterns including a first edge portion, which is adjacent to the bit line, and a second edge portion, which is opposite to the first edge portion. In addition, a bit line contact is provided between the first edge portion of each of the semiconductor patterns and the bit line, a back-gate electrode is provided between the semiconductor patterns and extends in a second direction, which is parallel to the top surface of the substrate and is non-parallel to the first direction, a separation pattern is provided on a bottom surface of the back-gate electrode, a storage node contact is provided on the second edge portion of each of the semiconductor patterns, a landing pad is provided on the storage node contact, and a data storage pattern is provided on the landing pad. In some embodiments, the separation pattern may extend between the semiconductor patterns, and the separation pattern may include an insulating material, which has a dielectric constant lower than SiON, and an impurity, which is included in the insulating material. The impurity may include at least one of N or F.

According to an embodiment of the inventive concept, a method of fabricating an integrated circuit device may include forming a second substrate on a first substrate; performing a removal process on a portion of the second substrate to form a first trench; forming a back-gate separation pattern to fill a lower portion of the first trench; forming a back-gate electrode on the back-gate separation pattern; and performing a removal process on another portion of the second substrate to form a second trench. The forming of the second trench may include dividing the second substrate into semiconductor patterns, which are spaced apart from each other in a first direction parallel to a top surface of the first substrate and are extended in a direction perpendicular to the top surface of the first substrate.

### BRIEF DESCRIPTION OF THE DRAWINGS

FIG. 1 is a block diagram illustrating an integrated circuit device according to an embodiment of the inventive concept.

FIGS. 2 and 3 are perspective views, each of which schematically illustrates an integrated circuit device according to an embodiment of the inventive concept.

FIG. 4 is a plan view illustrating an integrated circuit device according to an embodiment of the inventive concept.

FIG. 5 is a sectional view taken along a line A-A′ of FIG. 4.

FIGS. 6A to 6C are enlarged sectional views illustrating a portion ‘P1’ of FIG. 5.

FIG. 7 is a sectional view taken along a line A-A′ of FIG. 4.

FIGS. 8A to 8C are enlarged sectional views illustrating a portion ‘P2’ of FIG. 7.

FIGS. 9 to 13 are diagrams illustrating a method of fabricating an integrated circuit device, according to an embodiment of the inventive concept.

FIG. 14 is a sectional view illustrating a method of fabricating an integrated circuit device, according to an embodiment of the inventive concept.

### DETAILED DESCRIPTION

Example embodiments of the inventive concepts will now be described more fully with reference to the accompanying drawings, in which example embodiments are shown.

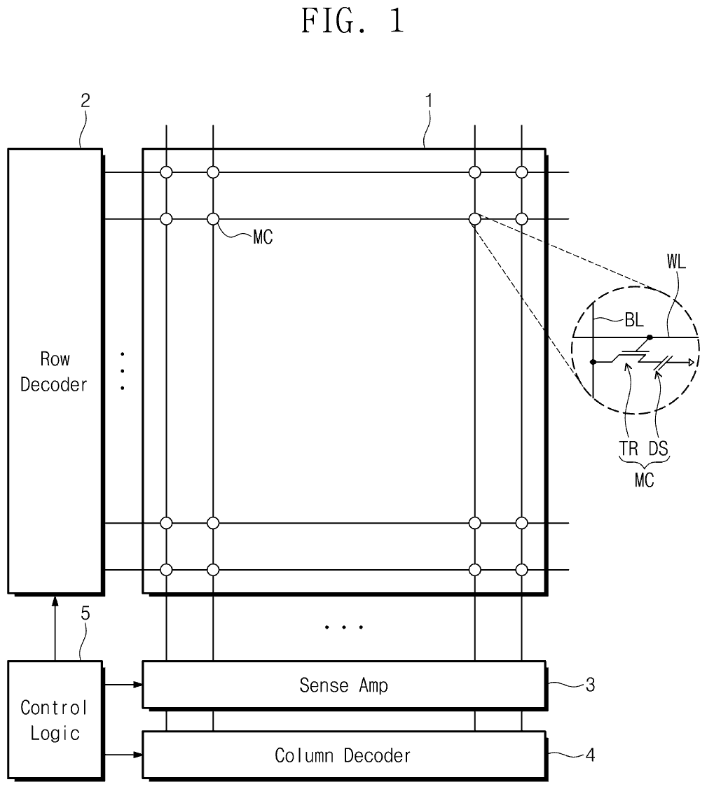

FIG. 1 is a block diagram illustrating an integrated circuit device according to an embodiment of the inventive concept. Referring to FIG. 1, an integrated circuit device may include a memory cell array 1, a row decoder 2, a sense amplifier 3, a column decoder 4, and a control logic 5. The memory cell array 1 may include a plurality of memory cells MC, which are two- or three-dimensionally arranged. Each of the memory cells MC may be provided between and connected to a word line WL and a bit line BL, which are provided to cross each other. Each of the memory cells MC may include a selection element TR and a data storing element DS. The selection element TR and the data storing element DS may be electrically connected to each other. The selection element TR may be connected to both the word line WL and the bit line BL. In other words, the selection element TR may be provided at an intersection of the word and bit lines WL and BL. The selection element TR may include a field effect transistor. The data storing element DS may include a capacitor, a magnetic tunnel junction pattern, or a variable resistor. As an example, the selection element TR may be a transistor whose gate, source, and drain terminals are connected to the word line WL, the bit line BL, and the data storing element DS, respectively.

The row decoder 2 may be configured to decode address information, which is input from the outside, and to select one of the word lines WL of the memory cell array 1, based on the decoded address information. The address information decoded by the row decoder 2 may be provided to a row driver (not shown), and in this case, the row driver may provide respective voltages to the selected one of the word lines WL and the unselected ones of the word lines WL, in response to the control of a control circuit. The sense amplifier 3 may be configured to sense, amplify, and output a difference in voltage between one of the bit lines BL, which is selected based on address information decoded by the column decoder 4, and a reference bit line. The column decoder 4 may establish a data transmission path between the sense amplifier 3 and an external device (e.g., a memory controller). The column decoder 4 may be configured to decode address information, which is input from the outside, and to select one of the bit lines BL, based on the decoded address information. The control logic 5 may generate control signals, which are used to control an operation of writing or reading data to or from the memory cell array 1.

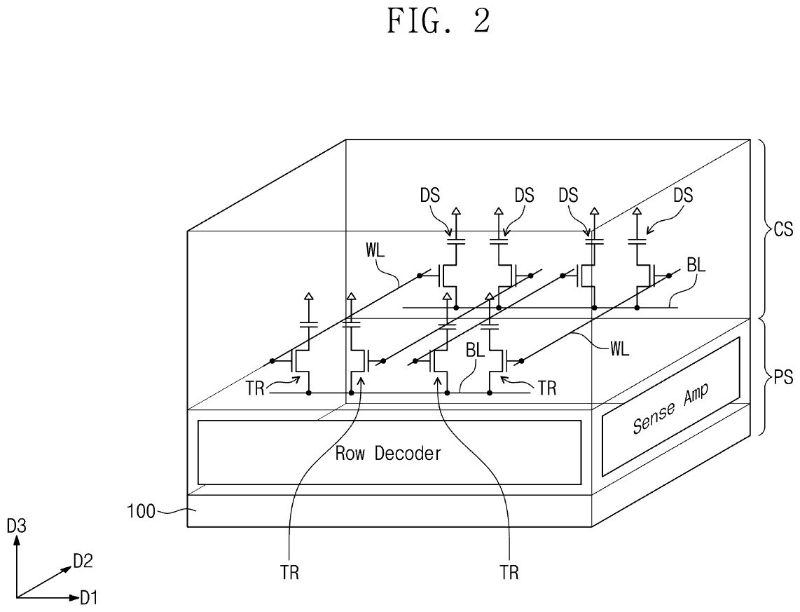

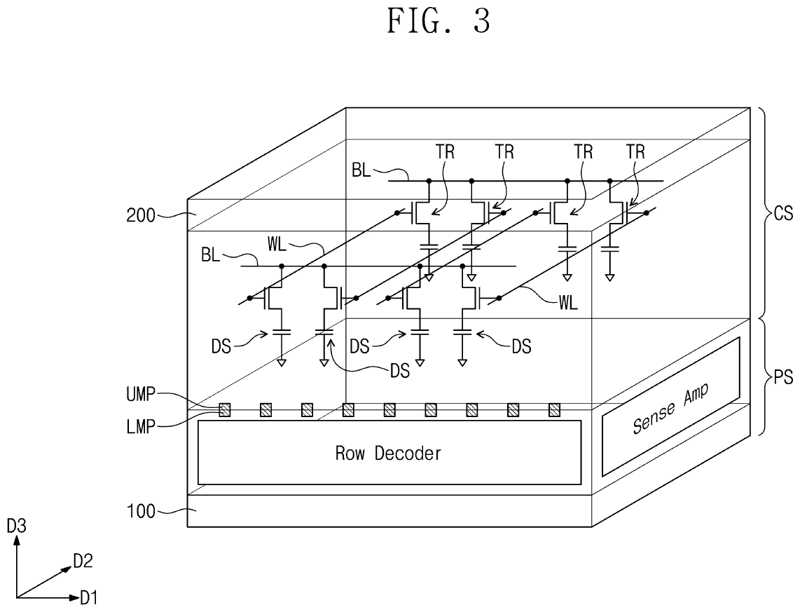

FIGS. 2 and 3 are perspective views, each of which schematically illustrates an integrated circuit device according to an embodiment of the inventive concept. Referring to FIGS. 2 and 3, an integrated circuit device may include a peripheral circuit structure PS on a substrate 100 and a cell array structure CS connected to the peripheral circuit structure PS. The substrate 100 may be a plate-shaped structure that is extended parallel to a plane defined by a first direction D1 and a second direction D2. The first and second directions D1 and D2 may be parallel to a top surface of the substrate 100 and may not be parallel to each other. A third direction D3 may be perpendicular to the top surface of the substrate 100 and may not be parallel to the first and second directions D1 and D2.

The peripheral circuit structure PS may include core and peripheral circuits formed on the substrate 100. The core and peripheral circuits may include the row and column decoders 2 and 4, the sense amplifier 3, and the control logics 5 described with reference to FIG. 1. The cell array structure CS may include the memory cell array 1 of FIG. 1, in which the memory cells MC of FIG. 1 are two- or three-dimensionally arranged. In an embodiment, the selection element TR of each of the memory cells MC (e.g., see FIG. 1) may include a vertical channel transistor (VCT). The vertical channel transistor may include a channel pattern having a length direction parallel to the third direction D3.

Referring to FIG. 2, the peripheral circuit structure PS may be provided on the substrate 100. The cell array structure CS may be provided on the peripheral circuit structure PS. Although not shown in the drawings, the peripheral circuit structure PS may be connected to the cell array structure CS through an additional contact. Referring to FIG. 3, an integrated circuit device may have a chip-to-chip (C2C) structure. The peripheral circuit structure PS may be provided on the substrate 100. First metal pads LMP may be provided in an upper portion of the peripheral circuit structure PS. The first metal pads LMP may be electrically connected to the core and peripheral circuits. The first metal pads LMP in the peripheral circuit structure PS may be bonded to second metal pads UMP in the cell array structure CS to be described below. Thus, the peripheral circuit structure PS may be bonded to the cell array structure CS. The cell array structure CS may be provided on a carrier substrate 200. The second metal pads UMP may be provided in a lower portion of the cell array structure CS. The second metal pads UMP may be electrically connected to the memory cell array 1 (e.g., see FIG. 1).

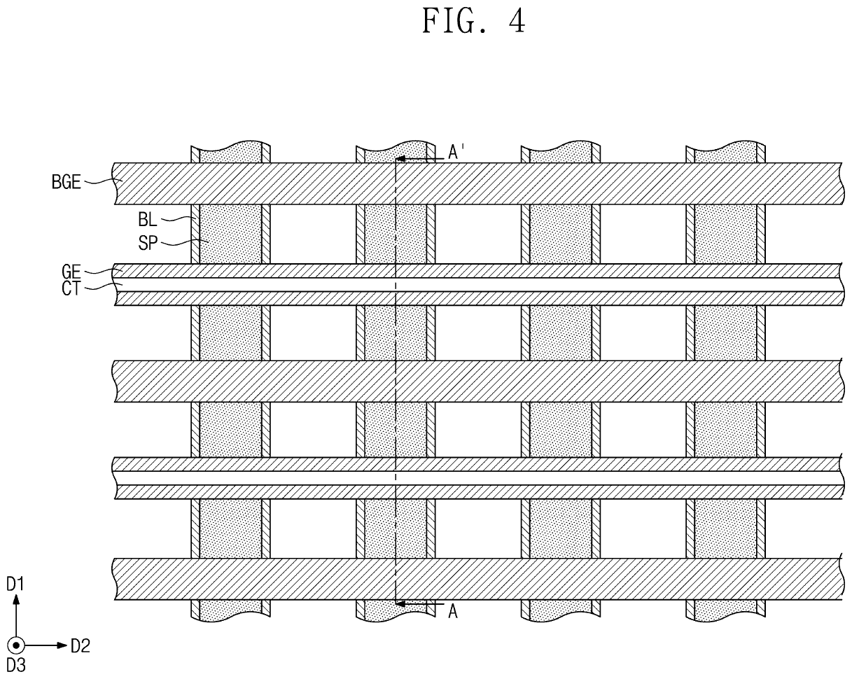

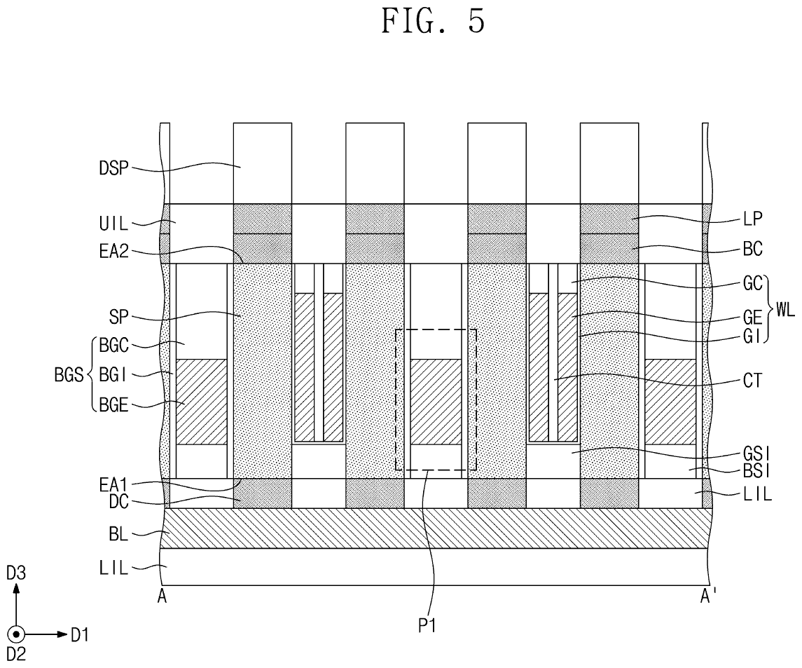

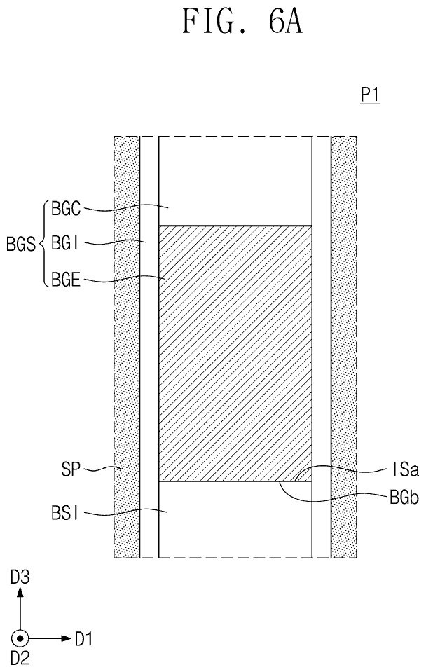

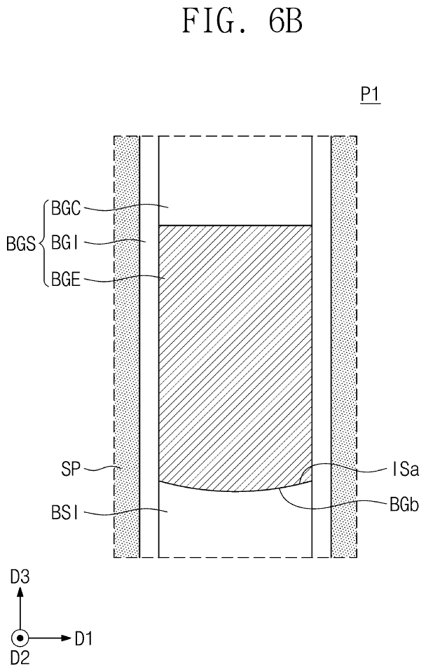

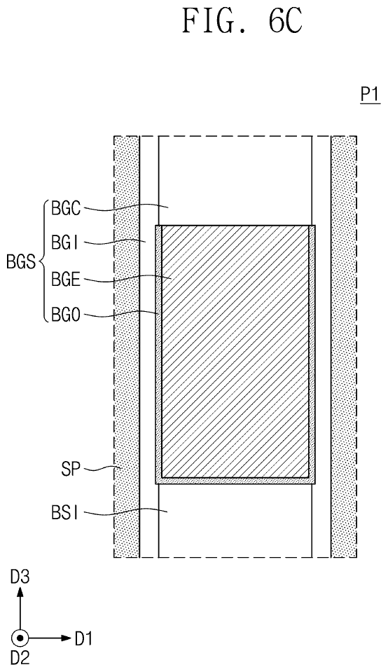

FIG. 4 is a plan view illustrating an integrated circuit device according to an embodiment of the inventive concept. FIG. 5 is a sectional view taken along a line A-A′ of FIG. 4. FIGS. 6A to 6C are enlarged sectional views illustrating a portion ‘P1’ of FIG. 5. FIGS. 4 and 5 are plan and sectional views illustrating elements in the cell array structure CS described with reference to FIGS. 2 and 3.

The integrated circuit device may include a lower insulating layer LIL. The lower insulating layer LIL may include an insulating material. In an embodiment, the lower insulating layer LIL may be provided in a lower portion of the cell array structure CS described with reference to FIG. 2. Here, the lower insulating layer LIL may be adjacent to and in contact with the peripheral circuit structure PS described with reference to FIG. 2. In addition, the peripheral circuit structure PS of FIG. 2 may be interposed between the substrate 100 and the lower insulating layer LIL described with reference to FIG. 2. In addition, the lower insulating layer LIL may include interconnection lines, which are connected to the core and peripheral circuits of the peripheral circuit structure PS described with reference to FIG. 2.

In an embodiment, the cell array structure CS (e.g., see FIG. 2) of the integrated circuit device may be inverted or flipped, and in this case, the lower insulating layer LIL may be provided in an upper portion of the cell array structure CS described with reference to FIG. 3. Here, the lower insulating layer LIL may be adjacent to and in contact with the carrier substrate 200 described with reference to FIG. 3. The plan and sectional views are presented to illustrate the cell array structure CS (e.g., see FIG. 2) that is in a non-inverted state, but although these drawings will be used to describe the integrated circuit device, the inventive concept is not limited to this example.

The bit line BL may be provided in the lower insulating layer LIL. The bit line BL in the lower insulating layer LIL may be extended in the first direction D1. The bit line BL may include a conductive material. In an embodiment, the bit line BL may be formed of or include at least one of doped semiconductor materials (e.g., doped silicon and doped germanium), metallic materials (e.g., Ti, Mo, W, Cu, Al, Ta, Ru, Ir, and Co), metal silicide materials (e.g., silicide materials containing Ti, Mo, W, Cu, Al, Ta, Ru, Ir, and Co), or metal nitride materials (e.g., nitride materials containing Ti, Mo, W, Cu, Al, Ta, Ru, Ir, and Co). The bit line BL may be a single layer or a composite layer. In an embodiment, a plurality of bit lines BL may be provided. The bit lines BL may be disposed to be spaced apart from each other in the second direction D2.

A bit line contact DC may be provided in the lower insulating layer LIL. The bit line contact DC may be provided on the bit line BL. The bit line contact DC may be interposed between a semiconductor pattern SP, which will be described below, and the bit line BL. Thus, the bit line BL may be connected to the semiconductor pattern SP through the bit line contact DC. The bit line contact DC may include a conductive material. In an embodiment, the bit line contact DC may include doped silicon. In an embodiment, a plurality of bit line contacts DC may be provided. The bit line contacts DC on each bit line BL may be spaced apart from each other in the first direction D1.

The semiconductor pattern SP may be provided on the bit line BL. The semiconductor pattern SP may be provided on a top surface of the bit line contact DC. The semiconductor pattern SP on the bit line BL may be extended in the third direction D3. In an embodiment, a plurality of semiconductor patterns SP may be provided. The semiconductor patterns SP on each bit line BL may be disposed to be spaced apart from each other in the first direction D1. The semiconductor patterns SP may be disposed to be spaced apart from each other in the second direction D2.

The semiconductor pattern SP may include a semiconductor material. In an embodiment, the semiconductor pattern SP may be formed of or include at least one of silicon (e.g., single crystalline silicon), germanium, or silicon-germanium. Alternatively, the semiconductor pattern SP may be formed of or include at least one of oxide semiconductor materials. Here, the oxide semiconductor materials may include at least one of InGaZnO, InGaSiO, InSnZnO, InZnO, ZnO, ZnSnO, ZnON, ZrZnSnO, SnO, HfInZnO, GaZnSnO, AlZnSnO, YbGaZnO, or InGaO, but the inventive concept is not limited to this example. In an embodiment, the semiconductor pattern SP may include indium gallium zinc oxide (IGZO). In an embodiment, the semiconductor pattern SP may include a two-dimensional semiconductor material. Here, the two-dimensional semiconductor material may include graphene, carbon nanotube, or combinations thereof.

The word line WL may be provided on a side surface of the semiconductor pattern SP. The word line WL may be interposed between the semiconductor patterns SP, which are adjacent to each other in the first direction D1. The word line WL may be extended in the second direction D2. In an embodiment, a plurality of word lines WL may be provided. The word lines WL may be disposed to be spaced apart from each other in the first direction D1. In an embodiment, a pair of the word lines WL, which are adjacent to each other in the first direction D1, may be interposed between the semiconductor patterns SP, which are adjacent to each other in the first direction D1. In an embodiment, a pair of the word lines WL, which are adjacent to each other in the first direction D1, may be spaced apart from each other, and a cutting pattern CT to be described below may be interposed between the pair of the word lines WL.

The word line WL may include a gate electrode GE, which is extended in the second and third directions D2 and D3, and a gate insulating pattern GI, which is placed between the semiconductor pattern SP and the gate electrode GE. The gate electrode GE may include a conductive material. In an embodiment, the gate electrode GE may be provided in the form of a single layer. In an embodiment, the gate electrode GE may be formed of or include at least one of metallic materials (e.g., Ti, Mo, W, Cu, Al, Ta, Ru, Ir, and Co), metal silicide materials (e.g., silicide materials containing Ti, Mo, W, Cu, Al, Ta, Ru, Ir, and Co), or metal nitride materials (e.g., nitride materials containing Ti, Mo, W, Cu, Al, Ta, Ru, Ir, and Co). The gate insulating pattern GI may be formed of or include at least one of silicon oxide or high-k dielectric materials. In the present specification, the high-k dielectric material may be defined as a material having a higher dielectric constant than that of silicon oxide.

A gate capping pattern GC may be provided on a top surface Ga of the gate electrode GE. The gate capping pattern GC may be interposed between the gate electrode GE and an upper insulating layer UIL. A side surface of the gate capping pattern GC may be covered with the gate insulating pattern GI. The gate capping pattern GC may include an insulating material. In an embodiment, the gate capping pattern GC may include at least one of silicon oxide or silicon nitride.

The cutting pattern CT may be interposed between the word lines WL, which are adjacent to each other in the first direction D1, to separate them from each other. The cutting pattern CT may be extended in the third direction D3. In an embodiment, the cutting pattern CT may include an insulating material.

A back-gate structure BGS may be provided on a side surface of the semiconductor pattern SP. The back-gate structure BGS may be interposed between the semiconductor patterns SP, which are adjacent to each other in the first direction D1. The back-gate structure BGS and the word line WL may be spaced apart from each other in the first direction D1, with the semiconductor pattern SP interposed therebetween. The back-gate structure BGS may be extended in the second direction D2, between the semiconductor patterns SP that are adjacent to each other in the first direction D1. In an embodiment, a plurality of back-gate structures BGS may be provided. The back-gate structures BGS may be formed to be spaced apart from each other in the first direction D1.

A threshold voltage of a transistor including the semiconductor pattern SP may be controlled by a voltage applied to the back-gate structure BGS. This may make it possible to more easily control the threshold voltage, compared to injecting impurities into the semiconductor pattern SP. Since the threshold voltage is controlled through the back-gate structure BGS, it may be possible to prevent the transistor from being unintentionally turned on.

The back-gate structure BGS may include a back-gate electrode BGE, a back-gate capping pattern BGC on the back-gate electrode BGE, and a back-gate insulating pattern BGI covering side surfaces thereof. The back-gate insulating pattern BGI may be interposed between a back-gate separation pattern BSI to be described below and the semiconductor pattern SP. In an embodiment, the back-gate electrode BGE may be formed of or include at least one of metallic materials (e.g., Ti, Mo, W, Cu, Al, Ta, Ru, Ir, and Co), metal silicide materials (e.g., silicide materials containing Ti, Mo, W, Cu, Al, Ta, Ru, Ir, and Co), or metal nitride materials (e.g., nitride materials containing Ti, Mo, W, Cu, Al, Ta, Ru, Ir, and Co). In an embodiment, the back-gate capping pattern BGC may include an insulating material. The back-gate insulating pattern BGI may be formed of or include at least one of silicon oxide or high-k dielectric materials.

A storage node contact BC may be provided on the semiconductor pattern SP. The storage node contact BC may be provided on a second edge portion EA2 of the semiconductor pattern SP. In an embodiment, the storage node contact BC may be provided on a top surface of the semiconductor pattern SP. The storage node contact BC may include a conductive material. In an embodiment, the storage node contact BC may include doped silicon. In an embodiment, a plurality of storage node contacts BC may be provided. The storage node contacts BC may be disposed to be spaced apart from each other in the first and second directions D1 and D2.

A landing pad LP may be provided on the storage node contact BC. The landing pad LP may be connected to the semiconductor pattern SP through the storage node contact BC. The landing pad LP may include a conductive material. In an embodiment, the landing pad LP may be formed of or include at least one of doped semiconductor materials (e.g., doped silicon and doped germanium), metallic materials (e.g., Ti, Mo, W, Cu, Al, Ta, Ru, Ir, and Co), metal silicide materials (e.g., silicide materials containing Ti, Mo, W, Cu, Al, Ta, Ru, Ir, and Co), or metal nitride materials (e.g., nitride materials containing Ti, Mo, W, Cu, Al, Ta, Ru, Ir, and Co).

In an embodiment, a plurality of landing pads LP may be provided. The landing pads LP may be disposed to be spaced apart from each other in the first and second directions D1 and D2. When viewed in a plan view, the landing pads LP may be arranged in various shapes (e.g., zigzag, matrix, and honeycomb shapes). The landing pad LP may have various shapes (e.g., circular, elliptical, rectangular, square, rhombus, and hexagonal shapes), when viewed in a plan view.

The upper insulating layer UIL may be provided to surround the storage node contact BC and the landing pad LP. The upper insulating layer UIL may include an insulating material. The upper insulating layer UIL may be a single layer or a composite layer. The upper insulating layer UIL may separate the storage node contacts BC from each other. The upper insulating layer UIL may separate the landing pads LP from each other.

A data storage pattern DSP may be provided on the landing pad LP. The data storage pattern DSP may be connected to the semiconductor pattern SP through the landing pad LP and the storage node contact BC. In an embodiment, a plurality of data storage patterns DSP may be provided. The data storage patterns DSP may be disposed to be spaced apart from each other in the first and second directions D1 and D2. The data storage pattern DSP may correspond to the data storing element DS described with reference to FIGS. 1 to 3.

In an embodiment, the data storage pattern DSP may be a capacitor including a bottom electrode, a dielectric layer, and a top electrode. In this case, the integrated circuit device may be a dynamic random access memory (DRAM) device. As another example, the data storage pattern DSP may include a magnetic tunnel junction pattern. In this case, the integrated circuit device may be a magnetic random access memory (MRAM) device. As other examples, the data storage pattern DSP may include a phase-change material or a variable resistance material. In this case, the integrated circuit device may be a phase-change random access memory (PRAM) device or a resistive random access memory (ReRAM) device. However, the inventive concept is not limited to these examples, and the data storage pattern DSP may include various structures and/or materials that can be used to store data therein.

The back-gate separation pattern BSI may be provided on a bottom surface of the back-gate structure BGS. The back-gate separation pattern BSI may be interposed between the bit line BL and the back-gate structure BGS. The back-gate separation pattern BSI may be interposed between the lower insulating layer LIL and the back-gate structure BGS. The back-gate separation pattern BSI may be interposed between the semiconductor patterns SP, which are adjacent to each other in the first direction D1. The back-gate separation pattern BSI may be enclosed by the back-gate insulating pattern BGI. In an embodiment, the back-gate separation pattern BSI may not include a seam therein.

The back-gate separation pattern BSI may include an insulating material. In an embodiment, the insulating material of the back-gate separation pattern BSI may have a dielectric constant that is smaller than SiON. In an embodiment, the dielectric constant of the insulating material of the back-gate separation pattern BSI may be less than or equal to 4.5. The insulating material of the back-gate separation pattern BSI may include at least one of SiO₂ or low-k dielectric materials. In the present specification, the low-k dielectric material may be defined as a material having a lower dielectric constant than that of silicon oxide.

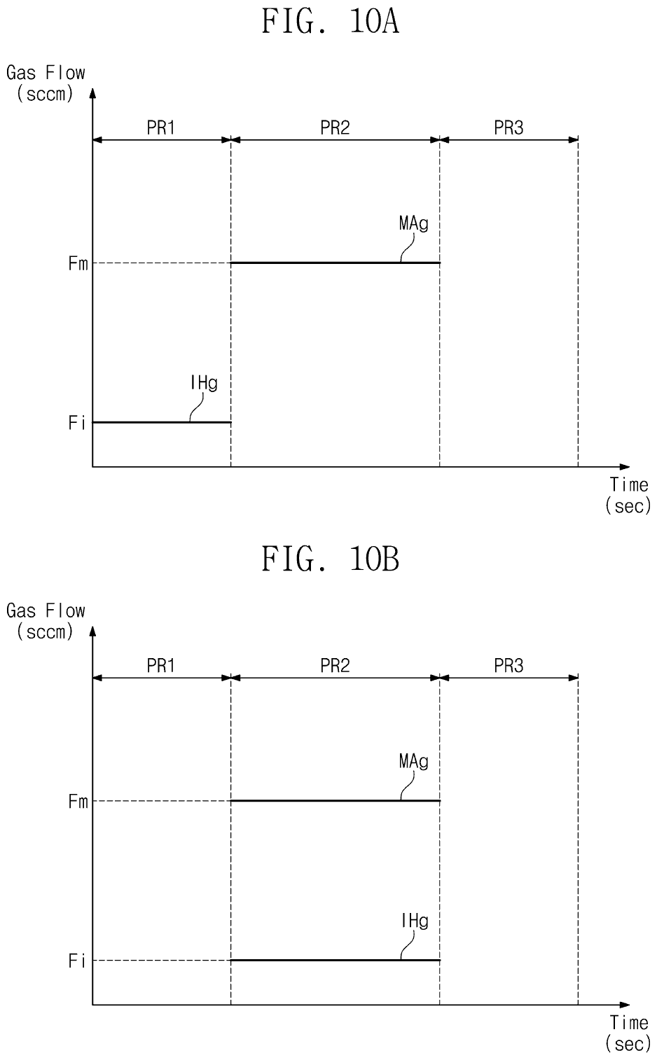

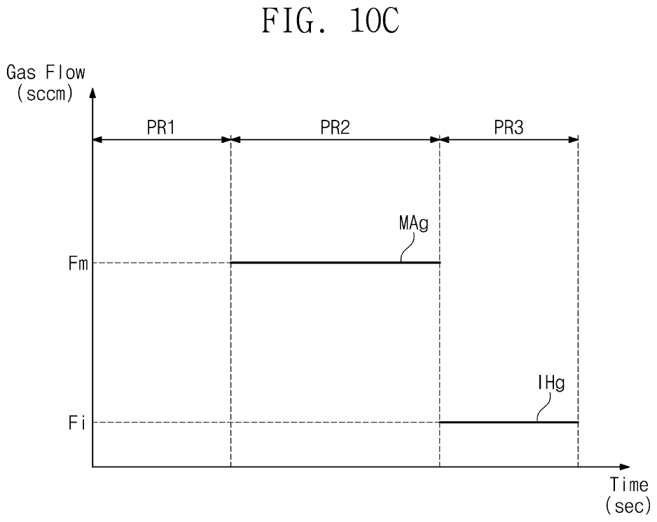

The back-gate separation pattern BSI may contain impurities in the insulating material. The impurity may be produced from a gas (e.g., a growth suppressing gas IHg to be described with reference to FIGS. 10A to 10C) suppressing a growth of the insulating material of the back-gate separation pattern BSI, in a process of forming the back-gate separation pattern BSI to be described below, and may be left in the insulating material even when the formation of the back-gate separation pattern BSI is finished. In an embodiment, the impurity may contain at least one of N or F. An atomic concentration of the impurity may range from 0.5 at % to 15 at %. In the case where the impurity contains N, the atomic concentration of N may range from 0.5 at % to 5 at %. In the case where the impurity contains F, the atomic concentration of F may range from 0.5 at % to 15 at %.

Referring to FIG. 6A, the back-gate separation pattern BSI may be provided on a bottom surface BGb of the back-gate electrode BGE. Since a top surface ISa of the back-gate separation pattern BSI is formed to have a substantially flat profile, the bottom surface BGb of the back-gate electrode BGE may also be formed to have a substantially flat profile. Referring to FIG. 6B, since the top surface ISa of the back-gate separation pattern BSI is formed to have a downwardly concave profile, the bottom surface BGb of the back-gate electrode BGE may be formed to have a downwardly convex profile.

Referring to FIGS. 6A and 6B, according to a process of forming the back-gate separation pattern BSI to be described below, the top surface ISa of the back-gate separation pattern BSI and the bottom surface BGb of the back-gate electrode BGE may be formed to have the afore-described profile. Since the back-gate separation pattern BSI is formed before the formation of the back-gate electrode BGE, it may be possible to omit a removal process on the bottom surface BGb of the back-gate electrode BGE, in the formation of the back-gate separation pattern BSI. Thus, the bottom surface BGb of the back-gate electrode BGE may have the afore-described profiles, rather than having an upwardly concave profile.

Referring to FIG. 6C, in the case where the back-gate electrode BGE includes a conductive material (e.g., a metallic material), the back-gate structure BGS may include a metal oxide pattern BGO interposed between the back-gate electrode BGE and the back-gate insulating pattern BGI and between the back-gate electrode BGE and the back-gate separation pattern BSI. The metal oxide pattern BGO may include an oxide material containing a metallic element.

In an embodiment, according to a process of forming the back-gate separation pattern BSI to be described below, the metal oxide pattern BGO may not be interposed between the back-gate insulating pattern BGI and the back-gate separation pattern BSI. Since the back-gate separation pattern BSI is formed before the formation of the back-gate electrode BGE, the back-gate separation pattern BSI may not be formed through a method of removing a portion of the back-gate electrode BGE and filling the removed portion with the back-gate separation pattern BSI. Thus, a portion of the back-gate insulating pattern BGI in contact with the back-gate separation pattern BSI may not be in contact with the back-gate electrode BGE in the fabrication process, and as a result, the metal oxide pattern BGO may not be formed on the portion of the back-gate insulating pattern BGI.

Referring back to FIGS. 4 and 5, a gate separation pattern GSI may be provided on a bottom surface of the word line WL. The gate separation pattern GSI may be provided on a bottom surface of the gate electrode GE. The gate separation pattern GSI may be interposed between the bit line BL and the word line WL. The gate separation pattern GSI may be interposed between the semiconductor patterns SP, which are adjacent to each other in the first direction D1. In an embodiment, the gate separation pattern GSI may not include a seam therein.

The gate separation pattern GSI may include an insulating material. In an embodiment, the insulating material of the gate separation pattern GSI may have a dielectric constant that is smaller than SiON. In an embodiment, the dielectric constant of the insulating material of the gate separation pattern GSI may be less than or equal to 4.5. As an example, the insulating material of the gate separation pattern GSI may include at least one of SiO₂ or low-k dielectric materials.

The gate separation pattern GSI may include an impurity in the insulating material. The impurity may be produced from a gas (e.g., the growth suppressing gas IHg to be described with reference to FIGS. 10A to 10C) suppressing a growth of the insulating material of the gate separation pattern GSI, in a process of forming the gate separation pattern GSI to be described below, and may be left in the insulating material even when the formation of the gate separation pattern GSI is finished. In an embodiment, the impurity may contain at least one of N or F. An atomic concentration of the impurity may range from 0.5 at % to 15 at %. In the case where the impurity contains N, the atomic concentration of N may range from 0.5 at % to 5 at %. In the case where the impurity contains F, the atomic concentration of F may range from 0.5 at % to 15 at %.

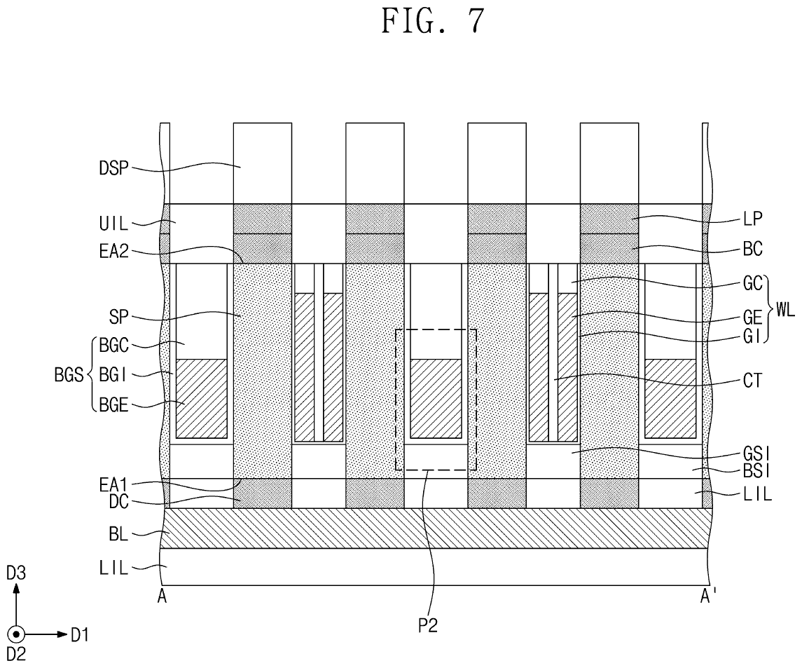

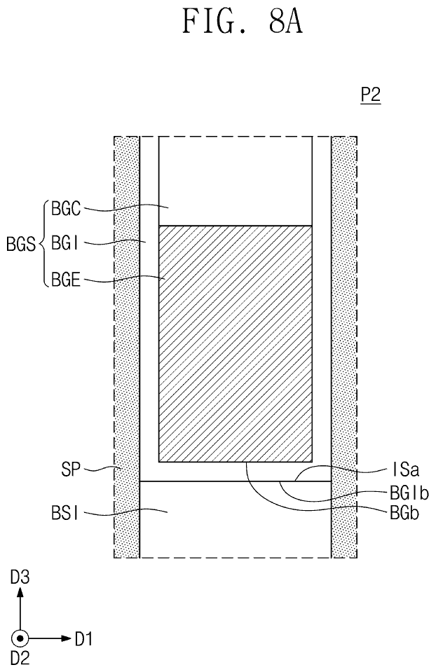

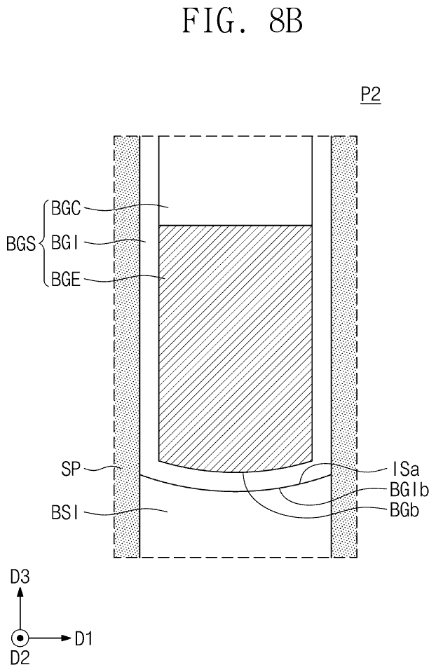

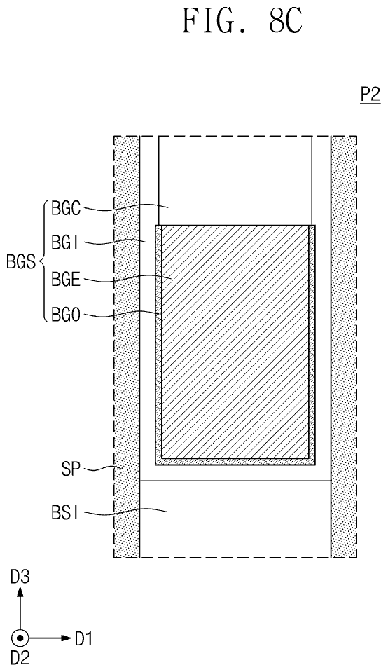

Hereinafter, an integrated circuit device according to an embodiment of the inventive concept will be described in more detail with reference to FIGS. 7 to 8C. In the following description, a previously-described element may be identified by the same reference number without repeating an overlapping description thereof, for concise description. In particular, FIG. 7 is a sectional view taken along a line A-A′ of FIG. 4. FIGS. 8A to 8C are enlarged sectional views illustrating a portion ‘P2’ of FIG. 7.

Referring to FIG. 7, the back-gate separation pattern BSI may be in contact with the semiconductor patterns SP. The back-gate separation pattern BSI may be spaced apart from the back-gate electrode BGE by the back-gate insulating pattern BGI. The back-gate insulating pattern BGI may cover opposite side surfaces and a bottom surface of the back-gate electrode BGE.

Referring to FIG. 8A, since the top surface ISa of the back-gate separation pattern BSI is formed to have a substantially flat profile, the bottom surface BGb of the back-gate electrode BGE and a bottom surface BGIb of the back-gate insulating pattern BGI may be formed to have a substantially flat profile. Referring to FIG. 8B, since the top surface ISa of the back-gate separation pattern BSI is formed to have a downwardly concave profile, the bottom surface BGb of the back-gate electrode BGE and the bottom surface BGIb of the back-gate insulating pattern BGI may be formed to have a downwardly convex profile. Referring to FIG. 8C, in the case where the back-gate electrode BGE includes a conductive material (e.g., a metallic material), the back-gate structure BGS may further include the metal oxide pattern BGO interposed between the back-gate electrode BGE and the back-gate insulating pattern BGI.

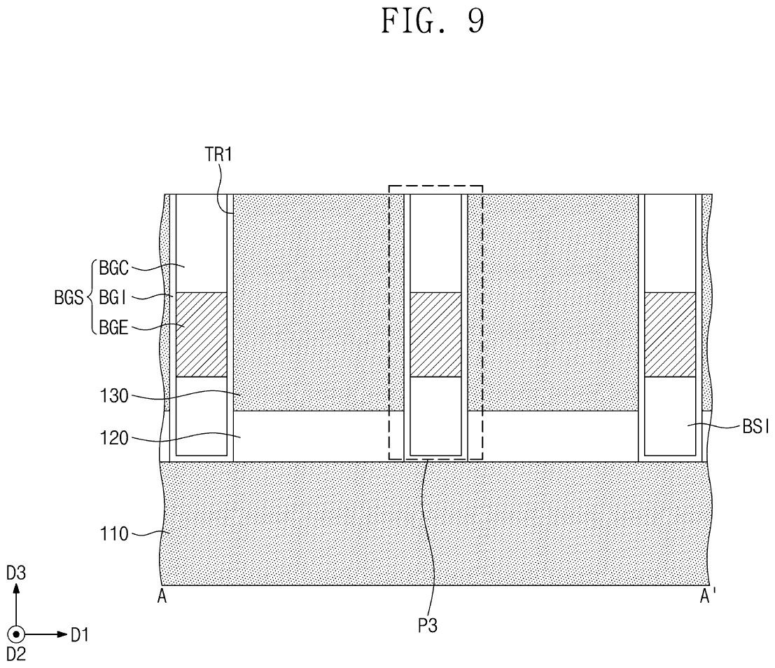

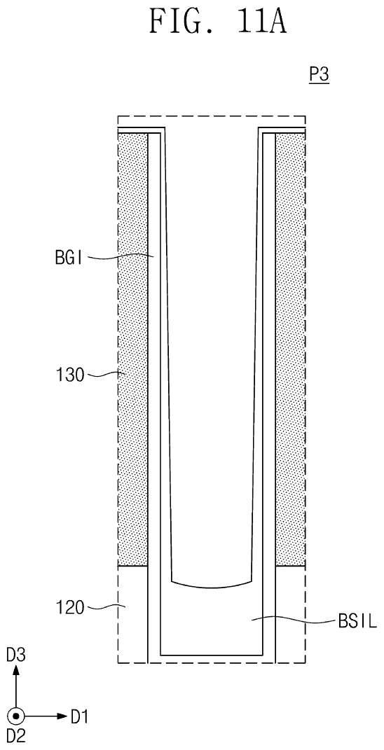

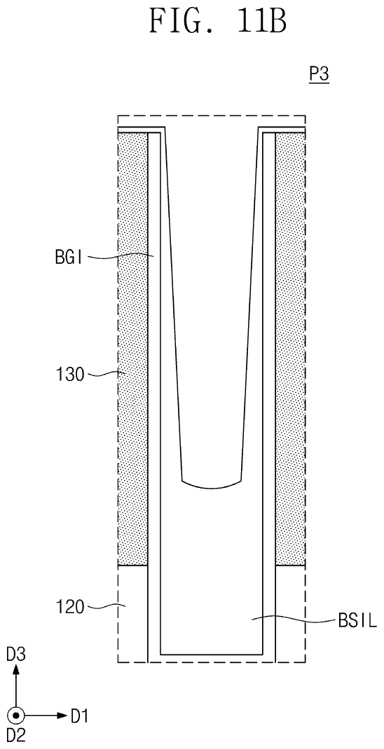

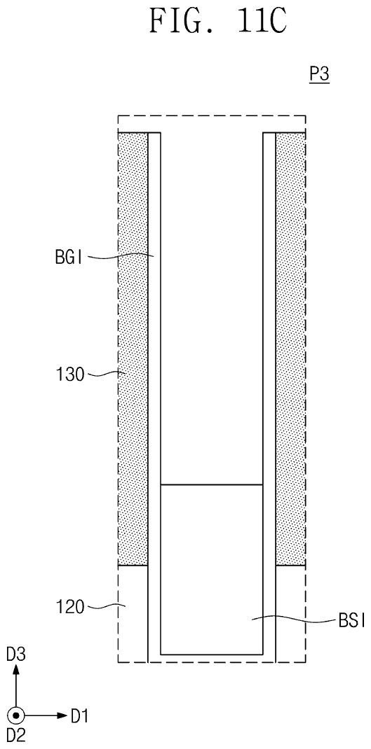

Hereinafter, a method of fabricating an integrated circuit device according to an embodiment of the inventive concept will be described with reference to FIGS. 9 to 14. In the following description, a previously-described element may be identified by the same reference number without repeating an overlapping description thereof, for concise description. In particular, FIGS. 9 to 13 are diagrams illustrating a method of fabricating an integrated circuit device, according to an embodiment of the inventive concept. In more detail, FIGS. 9, 12, and 13 are sectional views corresponding to the line A-A′ of FIG. 4. FIGS. 10A to 10C are graphs showing a change in flow rate of gases to be supplied into a chamber in a process of forming the back-gate separation pattern BSI. FIGS. 11A to 11C are enlarged sectional views corresponding to a portion ‘P3’ of FIG. 9 and concretely illustrating a process of forming the back-gate separation pattern BSI.

Referring to FIGS. 4 and 9, a first substrate 110 may be prepared. A dummy insulating layer 120 and a second substrate 130 may be sequentially formed on the first substrate 110. In an embodiment, the first substrate 110 and the second substrate 130 may include a semiconductor material. The dummy insulating layer 120 may include an insulating material. Next, a patterning process may be performed on the dummy insulating layer 120 and the second substrate 130 to form a first trench TR1 on the first substrate 110. The first trench TR1 may be formed to extend in the second direction D2. As a result of the formation of the first trench TR1, the dummy insulating layer 120 and the second substrate 130 may be divided into a plurality of dummy insulating layers 120 and a plurality of second substrates 130, respectively. The back-gate insulating pattern BGI may be formed to conformally cover the first trench TR1. The back-gate separation pattern BSI on the back-gate insulating pattern BGI may be formed to fill a lower portion of the first trench TR1.

According to an embodiment of the inventive concept, the back-gate separation pattern BSI may be formed before the formation of the back-gate electrode BGE. Thus, it may be possible to more easily form the back-gate separation pattern BSI, compare to a method of forming the back-gate electrode BGE, inverting or flipping the first substrate 110, and removing a portion of the back-gate electrode BGE to form the back-gate separation pattern BSI. Accordingly, it may be possible to improve productivity in a process of fabricating an integrated circuit device according to an embodiment of the inventive concept.

In the case where the formation of the back-gate separation pattern BSI includes removing a portion of the back-gate electrode BGE, the removal process may be performed on each of the back-gate electrodes BGE, and this may increase the dispersion in heights of the back-gate electrodes BGE. By contrast, according to an embodiment of the inventive concept, the back-gate separation pattern BSI may be formed before the formation of the back-gate electrode BGE, and thus, it may be possible to omit a process of removing the back-gate electrode BGE, in the formation of the back-gate separation pattern BSI. As a result, the dispersion in the heights of the back-gate electrodes BGE may be reduced, and the reliability of the integrated circuit device may be improved. The formation of the back-gate separation pattern BSI may include a bottom-up fill process. Hereinafter, the formation of the back-gate separation pattern BSI will be described in more detail with reference to FIG. 5 and FIGS. 10A to 11C.

Referring to FIG. 5 and FIGS. 10A to 10C, a process of forming the back-gate separation pattern BSI may be composed of a first process PR1, a second process PR2, and a third process PR3. The second process PR2 may be a step of supplying a main source gas MAg, which is used as a source gas for forming the insulating material of the back-gate separation pattern BSI, into the chamber. The main source gas MAg may be a precursor, which is used to form the insulating material of the back-gate separation pattern BSI in the first trench TR1. During the second process PR2, the main source gas MAg may be supplied into the chamber at a first flow rate Fm. Although the first flow rate Fm is illustrated to be constant, but the inventive concept is not limited to this example. The first flow rate Fm may increase or decrease over time. The first process PR1 may be a step that is performed before the supplying of the main source gas MAg, and the third process PR3 may be a step that is performed after the supplying of the main source gas MAg. At least one of the first and third processes PR1 and PR3 may be omitted.

In at least one of the first to third processes PR1 to PR3, the growth suppressing gas IHg may be supplied in the chamber. The growth suppressing gas IHg may inhibit the formation of the insulating material of the back-gate separation pattern BSI in the first trench TR1. In detail, a material, which is produced from the growth suppressing gas IHg, may be adsorbed on an inner surface of the first trench TR1, a top surface of the back-gate insulating pattern BGI, and a top surfaces of the semiconductor patterns SP. Thus, it may be possible to inhibit the formation of the insulating material of the back-gate separation pattern BSI on these elements. An amount of the material, which is produced from the growth suppressing gas IHg and is adsorbed on the elements, may increase as a height in the third direction D3 increases. That is, an amount of the insulating material of the back-gate separation pattern BSI formed on the elements may decrease as a height in the third direction D3 increases. Thus, the insulating material of the back-gate separation pattern BSI may be formed more in a lower portion of the first trench TR1 than in an upper portion of the first trench TR1. The back-gate separation pattern BSI may be locally formed in the lower portion of the first trench TR1 through the afore-describe bottom-up fill process.

In an embodiment, the growth suppressing gas IHg may include at least one of N₂, NH₃, or NF₃. The growth suppressing gas IHg may be supplied into the chamber at a second flow rate Fi. Although the second flow rate Fi is illustrated to be constant, but the inventive concept is not limited to this example. The second flow rate Fi may increase or decrease over time.

Referring to FIG. 10A, in the first process PR1, the growth suppressing gas IHg may be supplied into the chamber. In the second process PR2, the supplying of the growth suppressing gas IHg may be terminated, and then, the main source gas MAg may be supplied into the chamber. The third process PR3 may be omitted. The first and second processes PR1 and PR2 may be sequentially performed in one cycle, but the inventive concept is not limited to this example. For example, the first and second processes PR1 and PR2, which are sequentially performed, may be performed in two or more cycles.

Referring to FIG. 10B, the first process PR1 and the third process PR3 may be omitted. In the second process PR2, the main source gas MAg and the growth suppressing gas IHg may be supplied into the chamber. The second process PR2 may be performed one time, but the inventive concept is not limited to this example; for example, the second process PR2 may be performed two or more times.

Referring to FIG. 10C, the first process PR1 may be omitted. In the second process PR2, the main source gas MAg may be supplied into the chamber. In the third process PR3, the supplying of the main source gas MAg may be terminated, and then, the growth suppressing gas IHg may be supplied into the chamber. The second and third processes PR2 and PR3, which are sequentially performed, may be performed in two or more cycles.

A method of supplying the growth suppressing gas IHg (e.g., supply timing) is not limited to the example described with reference to FIG. 9 and FIGS. 10A to 10C and may be variously changed by those skilled in the art. Similarly, the supply duration of each of the main source gas MAg and the growth suppressing gas IHg, the first flow rate Fm, and the second flow rate Fi may also be variously changed by those skilled in the art.

Hereinafter, a process of forming the back-gate separation pattern BSI through the afore-described bottom-up fill process will be described in more detail with reference to FIGS. 11A to 11C. Referring to FIG. 11A, a back-gate separation layer BSIL may be formed in the first trench TR1 and on the top surfaces of the back-gate insulating pattern BGI and the semiconductor pattern SP. As described above, the back-gate separation layer BSIL may be thicker formed in the lower portion of the first trench TR1 than in the upper portion of the first trench TR1 and on the top surfaces of the back-gate insulating pattern BGI and the semiconductor pattern SP. Although the back-gate separation layer BSIL is illustrated to be formed in the upper portion of the first trench TR1 and on the top surfaces of the back-gate insulating pattern BGI and the semiconductor pattern SP, but the inventive concept is not limited to this example. For example, the back-gate separation layer BSIL may not be formed in the upper portion of the first trench TR1 and on the top surfaces of the back-gate insulating pattern BGI and the semiconductor pattern SP, according to the adsorption of the material, which is produced from the growth suppressing gas IHg described with reference to FIGS. 10A to 10C.

Referring to FIG. 11B, when the bottom-up fill process is finished, the back-gate separation layer BSIL may be formed to be thicker in the lower portion of the first trench TR1 than in the upper portion of the first trench TR1 and on the top surfaces of the back-gate insulating pattern BGI and the semiconductor pattern SP. Since the back-gate separation layer BSIL is formed to fill from the lower portion of the first trench TR1, a seam may not be formed in the back-gate separation layer BSIL.

Referring to FIG. 11C, a removal process may be performed to remove the back-gate separation layer BSIL from the upper portion of the first trench TR1, the top surface of the back-gate insulating pattern BGI, and the top surface of the semiconductor pattern SP. Thus, the back-gate separation layer BSIL may be divided into the back-gate separation patterns BSI, which are locally formed in the lower portions of the first trenches TR1, respectively.

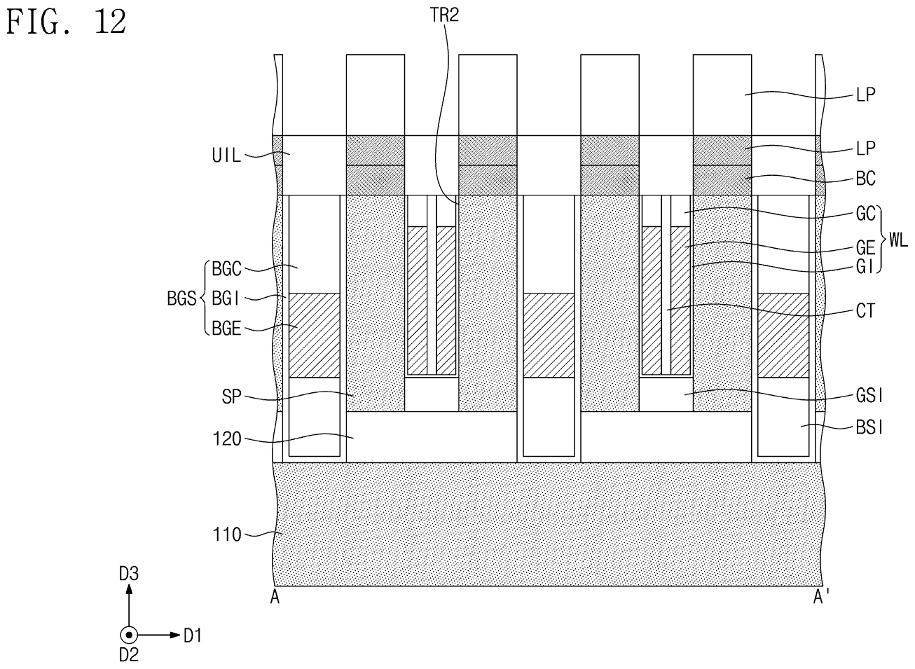

Referring to FIGS. 4 and 12, the back-gate electrode BGE and the back-gate capping pattern BGC may be sequentially formed on the back-gate separation pattern BSI. The back-gate separation pattern BSI, the back-gate electrode BGE, and the back-gate capping pattern BGC may constitute the back-gate structure BGS. Next, a second trench TR2 may be formed on the dummy insulating layer 120 through a removal process on a portion of the second substrate 130 of FIG. 9. The second substrate 130 of FIG. 9 may be divided into the semiconductor patterns SP, which are spaced apart from each other in the first direction D1, by the second trench TR2. The second trench TR2 may be formed to extend in the second direction D2.

The gate separation pattern GSI may be formed in a lower portion of the second trench TR2. The gate separation pattern GSI may be formed in the same or similar ways as the back-gate separation pattern BSI described with reference to FIGS. 9 to 11C.

According to an embodiment of the inventive concept, the formation of the gate separation pattern GSI may include performing a bottom-up fill process. Thus, the gate separation pattern GSI may be formed without repeating deposition and etching processes. As a result, the process of forming the gate separation pattern GSI may be simplified, and the productivity of the integrated circuit device may be improved.

The word line WL may be formed on the gate separation pattern GSI. The formation of the word line WL may include forming the gate insulating pattern GI to conformally cover an inner surface of the second trench TR2 and a top surface of the gate separation pattern GSI and forming the gate electrode GE and the gate capping pattern GC on the gate insulating pattern GI to sequentially fill the second trench TR2.

The cutting pattern CT may be formed to cross the word line WL in the third direction D3. Thus, between the semiconductor patterns SP, which are adjacent to each other in the first direction D1, each word line WL may be divided into a pair of the word lines WL, which are separated from each other in the first direction D1.

The storage node contact BC and the landing pad LP may be sequentially formed on the semiconductor pattern SP. The upper insulating layer UIL may be formed to enclose each of the storage node contact BC and the landing pad LP. The upper insulating layer UIL may be formed at various stages (e.g., with or without the formation of the storage node contact BC and/or the landing pad LP). Next, the data storage pattern DSP may be formed on the landing pad LP.

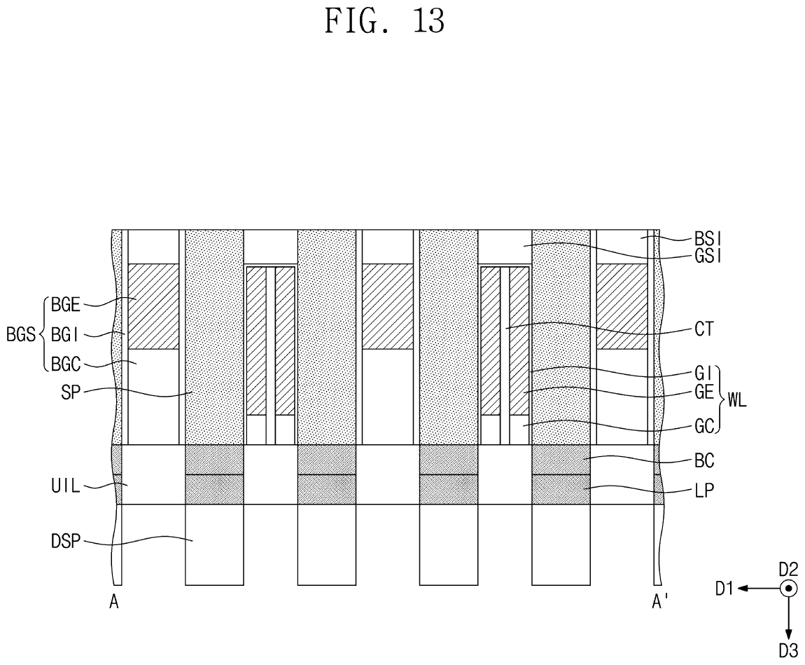

Referring to FIGS. 4 and 13, the first substrate 110 may be inverted or flipped. Thus, a bottom surface of the first substrate 110 may be exposed. The first substrate 110 and dummy insulating layer 120 (e.g., see FIG. 10) may be removed. Accordingly, the back-gate separation pattern BSI and the gate separation pattern GSI may be externally exposed.

Referring back to FIGS. 4 and 5, the bit line contact DC may be formed on the semiconductor pattern SP. The bit line BL may be formed on the bit line contact DC. The lower insulating layer LIL may be formed to cover the bit line contact DC and the bit line BL. The lower insulating layer LIL may be formed at various stages (e.g., with or without the formation of the bit line contact DC and/or the bit line BL).

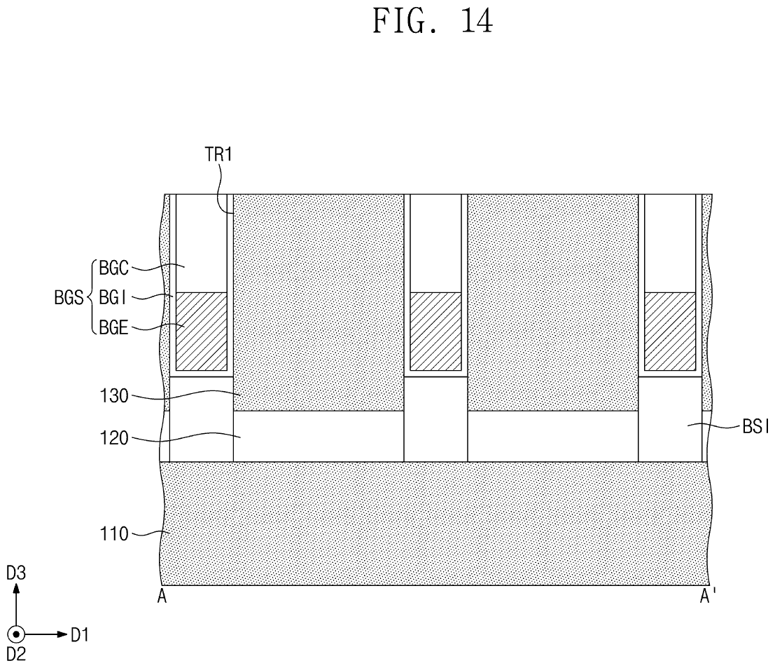

FIG. 14 is a sectional view illustrating a method of fabricating an integrated circuit device, according to an embodiment of the inventive concept. In more detail, FIG. 14 is a sectional view corresponding to a line A-A′ of FIG. 4. Referring to FIGS. 4 and 14, the back-gate separation pattern BSI may be formed in a lower portion of the first trench TR1, after the formation of the first trench TR1 described with reference to FIG. 9. The back-gate separation pattern BSI may be formed in the same or similar ways as described with reference to FIGS. 9 to 11C. Next, the back-gate structure BGS may be formed on the back-gate separation pattern BSI. Thereafter, the integrated circuit device described with reference to FIGS. 7 to 8C may be fabricated by the afore-described method.

According to an embodiment of the inventive concept, a back-gate separation pattern may be formed before the formation of a back-gate electrode. Thus, it may be possible to more easily form the back-gate separation pattern, compare to a method of forming the back-gate electrode, flipping a first substrate, and removing a portion of the back-gate electrode to form the back-gate separation pattern. In an embodiment, it may be possible to improve productivity in a process of fabricating an integrated circuit device according to an embodiment of the inventive concept.

In the case where the back-gate separation pattern is formed by removing a portion of the back-gate electrode, the removal process may be performed on each of the back-gate electrodes, and this may increase the dispersion in heights of the back-gate electrodes. By contrast, according to an embodiment of the inventive concept, the back-gate separation pattern may be formed before the formation of the back-gate electrode, and thus, it may be possible to omit a process of removing the back-gate electrode, in the formation of the back-gate separation pattern. As a result, the dispersion in the heights of the back-gate electrodes may be reduced, and the reliability of the integrated circuit device may be improved.

According to an embodiment of the inventive concept, the formation of a gate separation pattern may include performing a bottom-up fill process. Thus, the gate separation pattern may be formed without repeating deposition and etching processes. As a result, it may be possible to simplify the formation of the gate separation pattern and increase the productivity in a process of fabricating the integrated circuit device.

While example embodiments of the inventive concept have been particularly shown and described, it will be understood by one of ordinary skill in the art that variations in form and detail may be made therein without departing from the spirit and scope of the attached claims.

What is claimed is:

1. An integrated circuit device, comprising:
a substrate;
a bit line extending in a first direction, on the substrate;
a plurality of semiconductor patterns extending on the bit line;
a back-gate electrode extending between the plurality of semiconductor patterns and in a second direction, which is generally orthogonal to the first direction; and
a back-gate separation pattern extending on a bottom surface of the back-gate electrode and between the plurality of semiconductor patterns, said back-gate separation pattern comprising an insulating material, which has a dielectric constant lower than a dielectric constant of SiON and has an impurity therein selected from a group consisting of nitrogen (N) and fluorine (F).

2. The device of claim 1, wherein an atomic concentration of the impurity in the insulating material is in a range from 0.5 at % to 15 at %.

3. The device of claim 1, wherein the impurity is N at an atomic concentration in a range from 0.5 at % to 5 at %.

4. The device of claim 1, wherein the impurity is F at an atomic concentration in a range from 0.5 at % to 15 at %.

5. The device of claim 1, wherein a top surface of the back-gate separation pattern has a downwardly concave profile when viewed in cross-section.

6. The device of claim 1, wherein the bottom surface of the back-gate electrode has a downwardly convex profile when viewed in cross-section.

7. The device of claim 1, further comprising:
a back-gate insulating pattern extending between each of the plurality of semiconductor patterns and the back-gate electrode; and
a metal oxide pattern extending between the back-gate electrode and the back-gate insulating pattern.

8. The device of claim 7,
wherein the back-gate insulating pattern extends into a space between each of the plurality of semiconductor patterns and the back-gate separation pattern; and
wherein the metal oxide pattern does not extend between the back-gate insulating pattern and the back-gate separation pattern.

9. The device of claim 1, wherein the back-gate separation pattern does not include a seam therein.

10. The device of claim 1, wherein the insulating material of the back-gate separation pattern comprises at least one of SiO₂ and a dielectric material having a dielectric constant lower that a dielectric constant of silicon oxide.

11. The device of claim 1, further comprising:
a pair of gate electrodes extending between the semiconductor patterns and adjacent to each other in the first direction; and
wherein the back-gate electrode is spaced apart from the pair of gate electrodes, with one of the plurality of semiconductor patterns extending therebetween.

12. The device of claim 1, further comprising:
a gate separation pattern extending on a bottom surface of each of the pair of gate electrodes, and between the plurality of semiconductor patterns, said gate separation pattern comprising an insulating material, which has a dielectric constant lower than a dielectric constant of SiN and has an impurity therein selected from a group consisting of N and F.

13. An integrated circuit device, comprising:
a substrate;
a bit line extending in a first direction, on the substrate;
a plurality of semiconductor patterns extending on the bit line;
a back-gate electrode extending between the plurality of semiconductor patterns and in a second direction, which is generally orthogonal to the first direction; and
a back-gate separation pattern extending on a bottom surface of the back-gate electrode and between the plurality of semiconductor patterns, said back-gate separation pattern comprising an insulating material having an impurity therein selected from a group consisting of nitrogen (N) and fluorine (F); and
wherein an atomic concentration of the impurity ranges from 0.5 at % to 15 at %.

14. The device of claim 13, wherein the insulating material of the back-gate separation pattern comprises at least one of SiO₂ and a dielectric material having a dielectric constant lower that a dielectric constant of silicon oxide.

15. The device of claim 13, wherein the impurity is N at an atomic concentration in a range from 0.5 at % to 5 at %.

16. The device of claim 13, wherein the impurity is F at an atomic concentration in a range from 0.5 at % to 15 at %.

17. The device of claim 13, wherein a top surface of the back-gate separation pattern has a downwardly concave profile when viewed in cross-section.

18. The device of claim 13, further comprising:
a back-gate insulating pattern extending between each of the plurality of semiconductor patterns and the back-gate electrode; and
a metal oxide pattern extending between the back-gate electrode and the back-gate insulating pattern;
wherein the back-gate insulating pattern extends into a space between each of the plurality of semiconductor patterns and the back-gate separation pattern; and
wherein the metal oxide pattern is configured so that it does not extend between the back-gate insulating pattern and the back-gate separation pattern.

19. The device of claim 13, further comprising:
a pair of gate electrodes extending between the plurality of semiconductor patterns and extending adjacent to each other in the first direction;
a gate separation pattern on a bottom surface of each of the pair of gate electrodes;
wherein the back-gate electrode is spaced apart from the pair of gate electrodes, with one of the plurality of semiconductor patterns extending therebetween; and
wherein the gate separation pattern extends between the plurality of semiconductor patterns; and
wherein the gate separation pattern comprises an insulating material, which has a dielectric constant lower than a dielectric constant of SiN, and has an impurity therein selected from a group consisting of N and F.

20. An integrated circuit device, comprising:
a substrate;
a bit line extending in a first direction, on the substrate;
a plurality of semiconductor patterns extending on the bit line, with each of the plurality of semiconductor patterns including a first edge portion, which is adjacent to the bit line, and a second edge portion, which is opposite to the first edge portion;
a bit line contact extending between the first edge portion of each of the plurality of semiconductor patterns and the bit line;
a back-gate electrode extending between the semiconductor patterns and in a second direction different from the first direction;
a back-gate separation pattern on a bottom surface of the back-gate electrode;
a storage node contact on the second edge portion of each of the plurality of semiconductor patterns;
a landing pad on the storage node contact; and
a data storage pattern on the landing pad;
wherein the back-gate separation pattern extends between the plurality of semiconductor patterns, and includes an insulating material, which has a dielectric constant lower than a dielectric constant of SiON, and an impurity therein selected from a group consisting of nitrogen (N) and fluorine (F).
